(19) United States
(12) Patent Application Publication
(10) Pub. No.: US 2016/0031712 A1
(43) Pub. Date: Feb. 4, 2016

(54) APPARATUS FOR MANUFACTURING GRAPHENE, METHOD FOR MANUFACTURING THE SAME AND GRAPHENE MANUFACTURED BY THE METHOD

(71) Applicant: LG ELECTRONICS INC., Seoul (KR)

(72) Inventors: Jinsan MOON, Seoul (KR); Minseok CHOI, Seoul (KR); Mynghee JUNG, Seoul (KR)

(73) Assignee: LG ELECTRONICS INC., Seoul (KR)

(21) Appl. No.: 14/777,164

(22) PCT Filed: Apr. 28, 2014
(86) PCT No.: PCT/KR2014/003719

§ 371 Date: Sep. 15, 2015

(30) Foreign Application Priority Data
May 10, 2013 (KR) 10-2013-0053201

(51) Int. Cl. C01B 31/04; C23C 16/26

(52) U.S. Cl. CPC C01B 31/0453; C23C 16/26

(57) ABSTRACT

An apparatus for manufacturing high quality graphene, a method for manufacturing the same and graphene manufactured by the method are disclosed. The apparatus for manufacturing graphene includes a first chamber for supplying a carbon source under a first condition, a second chamber for supplying a carbon source under a second condition, a connector for connecting the first chamber to the second chamber, and a feeder for continuously supplying a catalyst metal to the first chamber and the second chamber.

### TECHNICAL FIELD

The present invention relates to graphene, more particularly, to an apparatus for manufacturing high quality graphene, a method for manufacturing the same and graphene manufactured by the method.

### BACKGROUND ART

Substances containing carbon atoms include fullerene, carbon nanotube, graphene and graphite. Of these, graphene is a single atom layer whose structure is a two-dimensional planar array of carbon atoms.

In particular, graphene has considerably stable and superior electrical, mechanical and chemical properties as well as excellent conductivity and thus more rapidly carries electrons than silicone and enables application of higher electrical current than copper, which has been actively researched since it was demonstrated through experimentation based on discovery of a method of separating graphene from graphite in 2004.

Graphene has attracted considerable attention as a base material for electronic circuits because it may be produced on a large scale and has electrical, mechanical and chemical stability as well as excellent conductivity.

In addition, electrical properties of graphene may change according to crystal direction of graphene with a predetermined thickness. For this reason, electrical properties are obtained in a direction selected by a user and devices can thus be easily designed. Accordingly, graphene is effectively used for carbon-based electronic or electromagnetic devices.

These properties of graphene may be greatly varied according to growth conditions.

### DISCLOSURE

### Technical Problem

An object of the present invention devised to solve the problem lies in an apparatus for manufacturing graphene which continuously grows high quality graphene by forming graphene under different conditions, a method for manufacturing graphene and graphene manufactured by the method.

### Technical Solution

The object of the present invention can be achieved by providing an apparatus for manufacturing graphene including a first chamber for supplying a carbon source under a first condition, a second chamber for supplying a carbon source under a second condition, a connector for connecting the first chamber to the second chamber, and a feeder for continuously supplying a catalyst metal to the first chamber and the second chamber.

The first condition may be configured to increase a size of seeds of graphene.

The first condition may include a lower partial pressure of carbon source than that of the second condition.

The first condition may include a temperature higher than that of the second condition.

The second condition may be configured to fill gaps between the seeds and to form graphene.

The feeder may include a feed roll disposed at one side of the first chamber, the feed roll supplying the catalyst metal, and a wind roll disposed at the other side of the second chamber, the wind roll winding the catalyst metal and supplying the catalyst metal in the form of a roll.

The apparatus may further include a third chamber for pre-treatment disposed at one side of the first chamber.

In another aspect of the present invention, provided herein is a method for manufacturing graphene including continuously supplying a catalyst metal to a first chamber and a second chamber using a feeder, supplying a carbon source to the first chamber to form graphene on the catalyst metal under a first condition, and supplying a carbon source to the second chamber to form graphene on the catalyst metal under a second condition.

The method may further include thermally treating the catalyst metal.

In another aspect of the present invention, provided herein is a method for manufacturing graphene including continuously supplying a catalyst metal to a first area and a second area having different conditions, forming graphene on the catalyst metal in the first area under a first condition, and carrying the catalyst metal in the second area and supplying a carbon source to the second area to form graphene under a second condition in a region in which graphene is formed under the first condition.

The first area and the second area may be inner parts of a first chamber and a second chamber which are different from each other.

In a further aspect of the present invention, provided herein is graphene manufactured by the method described above.

### Advantageous Effects

According to the present invention, first, upon growth of graphene, the graphene is grown in separate areas, i.e., an area to control seed density of graphene upon growth of the graphene and an area to fill gaps between seeds and complete growth of graphene, thereby continuously forming high-quality graphene thin films.

As such, formation areas having two or more conditions are provided, thereby forming graphene while continuously supplying the catalyst metal and greatly improving graphene quality.

The quality improvement can be maximized and growth time of graphene can be thus greatly shortened by providing separate chambers having different conditions.

The effects are not limited to those described above and other effects not described herein will be clearly understood by those skilled in the art from the following description.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 is a schematic view illustrating an example of an apparatus for manufacturing graphene;

FIGS. 2 to 4 are images illustrating seed densities of graphene according to growth conditions;

FIG. 5 is a schematic view illustrating another example of an apparatus for manufacturing graphene; and

FIG. 6 is a flowchart illustrating a method for manufacturing graphene.

### BEST MODEL

Reference will now be made in detail to the preferred embodiments of the present invention, examples of which are illustrated in the accompanying drawings.

However, the present invention allows various modifications and variations and specific embodiments thereof are exemplified with reference to drawings and will be described in detail. The present invention should not be construed as limited to the embodiments set forth herein and includes modifications, variations, equivalents, and substitutions compliant with the spirit or scope of the present invention defined by the appended claims.

It will be understood that when an element such as a layer, area or substrate is referred to as being “on” another element, it can be directly on the element, or one or more intervening elements may also be present therebetween.

In addition, it will be understood that although terms such as “first” and “second” may be used herein to describe elements, components, areas, layers and/or regions, the elements, components, areas, layers and/or regions should not be limited by these terms.

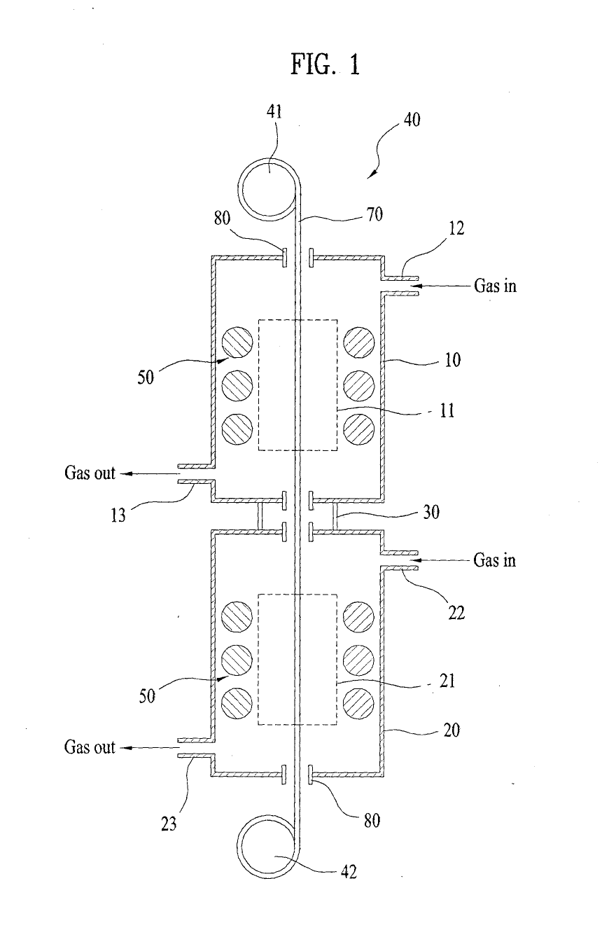

FIG. 1 is a schematic view illustrating an example of an apparatus for manufacturing graphene.

As shown in FIG. 1, the apparatus for manufacturing graphene may include two formation areas 11 and 12 having different conditions and a feeder 40 for continuously supplying a catalyst metal 70 such that the catalyst metal 70 passes through the formation areas 11 and 12.

That is, the apparatus for manufacturing graphene may include a first chamber 10 and a second chamber 20 connected to the first chamber 10, wherein the first chamber 10 and the second chamber 20 have the formation areas 11 and 12, respectively, and a feeder 40 for continuously supplying the catalyst metal 70 through the first chamber 10 and the second chamber 20.

Here, the first chamber 10 and the second chamber 20 may include gas inlets 12 and 22 and gas outlets 13 and 23, respectively. Accordingly, a carbon source which forms graphene on the catalyst metal 70 may be fed to the respective chambers 10 and 20 through the gas inlets 12 and 22.

In addition, the respective chambers 10 and 20 include a heater 50 and formation areas 11 and 12 adjacent to the heater 50 are defined in the respective chambers 10 and 20.

That is, the catalyst metal 70 is heated in the formation areas 11 and 12 using the heater 50, and a carbon-containing gas, which is a reaction gas (feed gas), is fed as a carbon source to form graphene on the catalyst metal 70.

The reaction gas (CxHx) is a carbon-containing compound which may be a compound having 6 carbon atoms or less, a compound having 4 carbon atoms or less or a compound having 2 carbon atoms or less. For example, a compound containing carbon and hydrogen (CxHx) may be used as the reaction gas.

In some cases, the formation areas 11 and 12 may be implemented in one chamber.

Meanwhile, the first chamber 10 and the second chamber 20 may be connected to each other through a connector 30 while maintaining air-tightness.

The feeder 40, which continuously supplies the catalyst metal 70 through the first chamber 10 and the second chamber 20, may feed the catalyst metal 70 in the form of a roll using rollers 41 and 42.

That is, the feeder 40 may include a feed roll 41 which is disposed at a side of the first chamber 10 and feeds the catalyst metal 70.

In addition, the apparatus may include a wind roll 42 which is disposed at the other side of the second chamber 20, i.e., the position disposed after the catalyst metal 70 supplied from the feed roll 41 passing through the first chamber 10 and second chamber 20, and winds the catalyst metal 70.

Accordingly, the catalyst metal 70 is fed from the feed roll 41 and is continuously carried while passing through the first chamber 10 and the second chamber 20. Graphene is formed on the catalyst metal 70.

In this case, an airtight member 80 may be provided in a region in which the catalyst metal 70 is carried. That is, an airtight member 80 may be disposed in a portion of the first chamber 10 through which the catalyst metal 70 is fed and discharged, and a portion of the second chamber 20 through which the catalyst metal 70 is fed and discharged.

Meanwhile, air-tightness of a region where the first chamber 10 is connected to the second chamber 20 may be maintained through the connector 30. In this region, the airtight member 80 may be omitted.

In the apparatus for manufacturing graphene, a carbon source may be fed to the first chamber 10 and the second chamber 20. At this time, a carbon source may be fed to the first chamber 10 under a first condition and may be fed to the second chamber 20 under a second condition.

The first and second conditions may include temperature, partial pressures of gases, pressure and atmosphere gas.

By satisfying different certain conditions under which graphene is grown in the first chamber 10 and the second chamber 20, graphene can be grown while the catalyst metal 70 continuously passes through the first chamber 10 and the second chamber 20.

For example, density of graphene seed may be varied according to partial pressure of the carbon source. Generally, as partial pressure of the carbon source decreases, seed density decreases.

The seed is an island-shaped substance which is present in an initial formation stage of graphene before graphene is grown into a complete layer. The seed may be a flake island constituting one grain. Commonly, one grain has one crystal surface.

Properties of graphene, for example, electrical properties, may be greatly varied according to growth conditions of graphene.

As size of the graphene flake island increases, grain boundary of the graphene decreases.

As described above, because one grain has the same crystal surface, the expression “graphene has many grain boundaries” means that graphene has different grain boundaries. Accordingly, the many grain boundaries may cause deterioration in electrical properties. That is, as the grain boundary decreases, electrical properties of graphene are improved.

Accordingly, when graphene having few grain boundaries is grown, high-quality graphene can be formed.

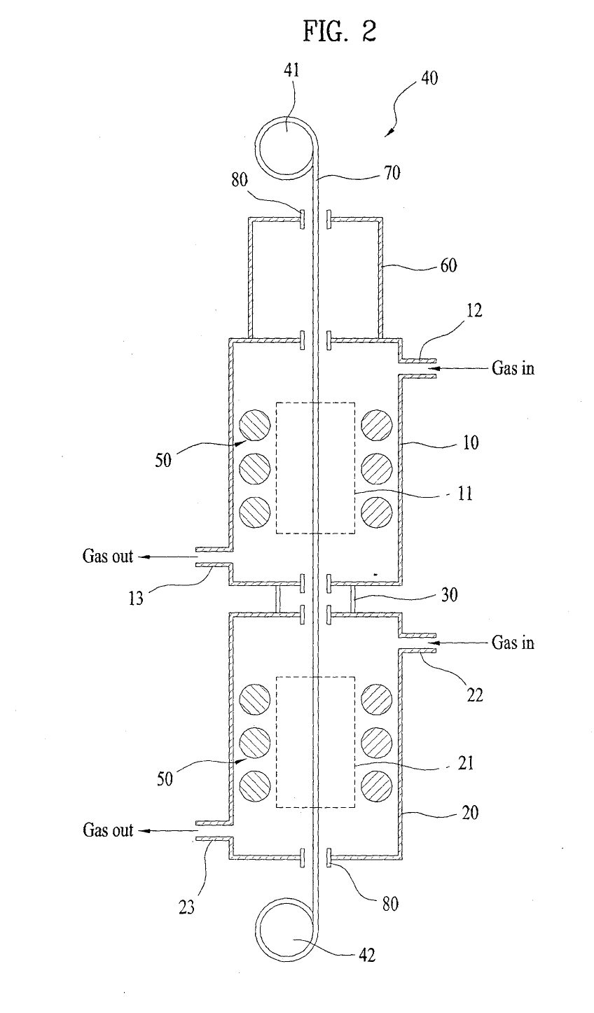

FIGS. 2 to 4 illustrate graphene grown at different seed densities. In the drawings, the graphene is incompletely grown.

FIG. 2 shows seeds having a considerably low density, that is, grains having a considerably small size. Grain size may be increased, as shown in FIGS. 3 and 4.

That is, FIG. 3 shows a seed 81 having a larger size than that of FIG. 2 and FIG. 4 shows a seed 82 having a larger size than that of FIG. 3.

However, conditions to increase seed density may be different from conditions to fill gaps between the seeds and complete graphene growth.

Accordingly, graphene is grown in separate areas, i.e., an area to control seed density of graphene upon growth of the graphene and an area to fill gaps between seeds and complete growth of graphene, thereby continuously forming high-quality graphene thin films.

That is, in the first chamber 10, a first condition is configured to increase a seed size of graphene and the graphene is grown under the first condition.

In addition, in the second chamber 10, a second condition is configured to fill gaps between seeds and complete growth of graphene and graphene is grown under the second condition.

As such, graphene is formed in formation areas 11 and 21 having two or more conditions, while the catalyst metal 70 is continuously fed, thereby greatly improving qualities of graphene.

The improvement of qualities can be maximized and growth time of graphene can thus be greatly shortened by providing separate chambers having different conditions.

The first condition may include a lower partial pressure of carbon source than that of the second condition. In some cases, a carrier gas may be injected together with the carbon source.

As the carrier gas, a gas such as hydrogen (H2), argon (Ar) or nitrogen (N2) may be used alone or in combination thereof.

In addition, the first condition may have a temperature equal to or higher than that of the second condition.

Meanwhile, as described above, two or more graphene growth conditions may be implemented by providing two or more chambers.

That is, a separate chamber to implement growth conditions such as a third condition and other conditions may be connected.

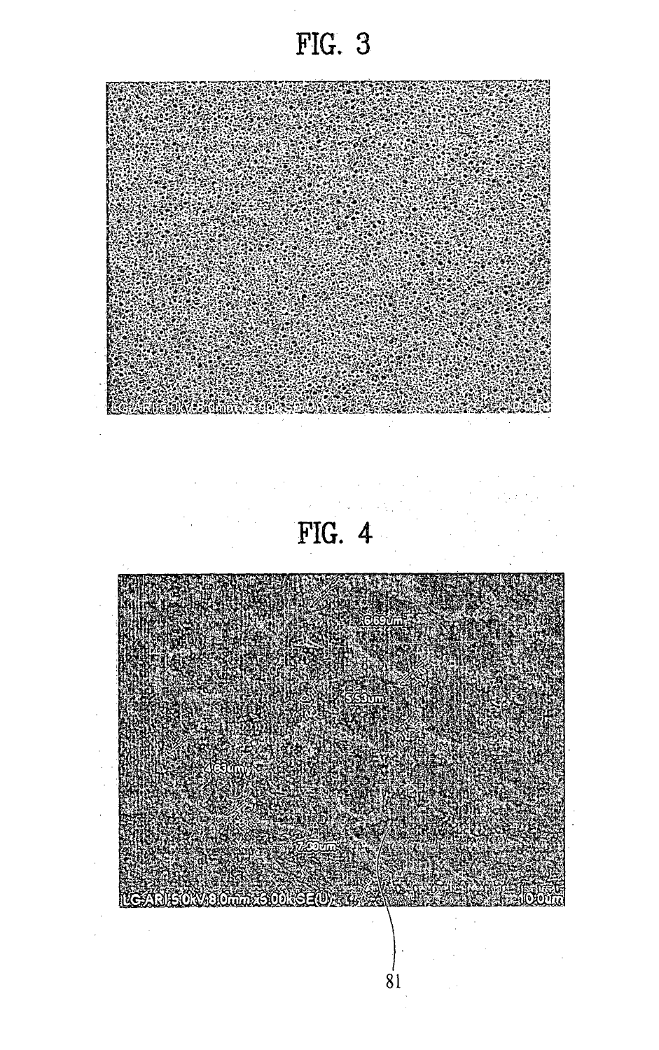

FIG. 5 illustrates another example of an apparatus for manufacturing graphene wherein a third chamber 60 is further provided at a side of the first chamber 10.

In the third chamber 60, pre-treatment of the catalyst metal 70 to grow graphene may be performed.

For example, the pre-treatment may be thermal treatment of the catalyst metal 70. In this case, oxides formed on catalyst metal 70 can be reduced by performing thermal treatment while supplying the carrier gas described above.

The feeder 40 for supplying the catalyst metal 70 may continuously feed the catalyst metal 70 through the third chamber 60 to the first chamber 10 and the second chamber 20.

Accordingly, as described above, an airtight member 80 may be provided in a region where the catalyst metal 70 is injected. In addition, separate gas inlets and gas outlets (not shown) may be provided in the third chamber 50.

Other elements not described herein may be the same as contents described with reference to FIG. 1.

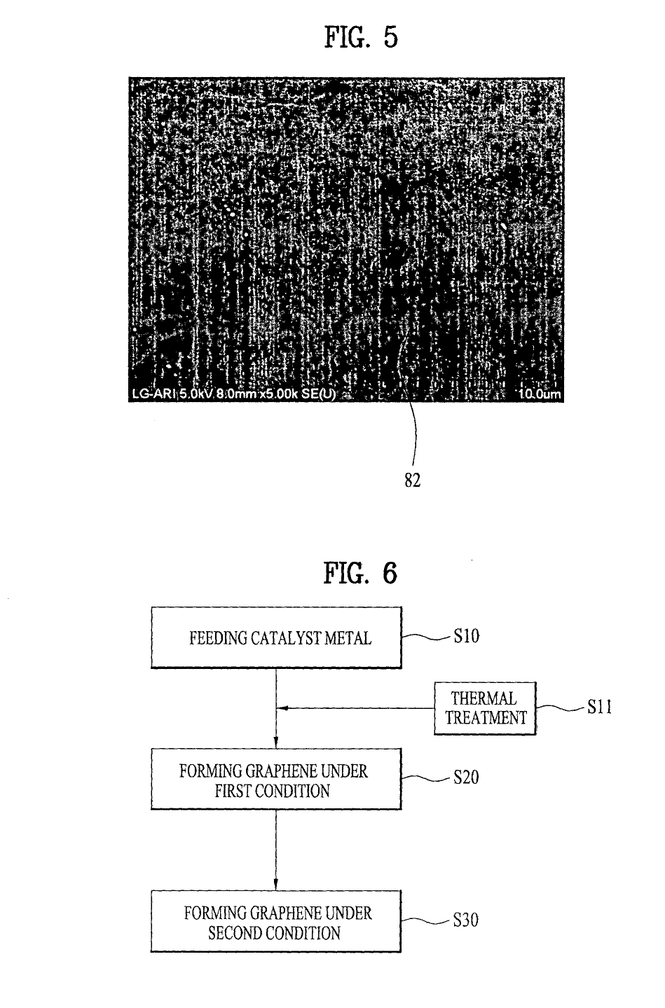

FIG. 6 is a flowchart illustrating a method for manufacturing graphene using the graphene manufacturing apparatus. Hereinafter, a process for manufacturing graphene will be described with reference to the drawings.

First, a catalyst metal 70 is loaded using a feeder 40 and fed to formation areas 11 and 12 (S10).

That is, the catalyst metal 70 is fed from a feed roll 41, passes through a first chamber 10 and a second chamber 20 and is loaded and fed such that the catalyst metal 70 is wound on a wind roll 42.

In the case in which a third chamber 60 is used, the catalyst metal 70 passes through the third chamber 60.

Then, a carbon source and/or a carrier gas are fed to the respective chambers 10, 20 and 60 under corresponding conditions and a temperature suited to the corresponding conditions is set using the heater 50.

That is, in the third chamber 60, temperature and flow of carrier gas are controlled according to conditions of thermal treatment.

In addition, in the first chamber 10, temperature and flow of carbon source or carrier gas are controlled under conditions configured to improve seed density.

In addition, in the second chamber 20, temperature and flow of carbon source or carrier gas are controlled under conditions configured to fill gaps between the seeds and complete growth of graphene.

In the case in which a third chamber 60 is provided, thermal treatment (S11) may be performed in the third chamber 60. However, in the case in which the third chamber 60 is not provided, the thermal treatment may be performed in the first chamber 10.

Then, when all the conditions are satisfied, the feeder 40 is operated to continuously grow graphene while moving the catalyst metal 60.

That is, the catalyst metal 60 passes through the first chamber 10 to form graphene under the first condition described above (S20).

Then, the catalyst metal 60 passes through the second chamber 20 to form graphene under the second condition described above (S30).

As described above, the first condition may have a low partial pressure of carbon source as compared to the second condition. In addition, the first condition may have an equal or high temperature as compared to the second condition.

Graphene may be formed on the catalyst metal 60 by chemical vapor deposition (CVD) using the apparatus for manufacturing graphene.

The catalyst metal 60 may be a metal such as Ni, Co, Fe, Pt, Au, Al, Cr, Cu, Mg, Mn, Mo, Rh, Si, Ta, Ti, W, U, V or Zr. In addition, the catalyst metal 60 may be used in the form of a foil having a thickness of about 10 μm to about 10 mm.

As such, the catalyst metal 60 can maintain tension using the feed roll 41 and the wind roll 42.

Formation of the graphene may be carried out at a temperature of about 300° C. to about 1,500° C.

After formation of graphene on the catalyst metal 60 through this process, a temperature of the heater 50 is lowered.

Then, a vacuum pump (not shown) is operated to remove remaining reaction gas through exhausts 13 and 23.

Meanwhile, embodiments of the present invention are provided for better understanding of the present invention and are not to be construed as limiting the scope of the invention. It will be apparent to those skilled in the art that various modifications and variations can be made in the present invention without departing from the spirit or scope of the invention.

### INDUSTRIAL APPLICABILITY

According to the present invention, formation areas having two or more conditions are provided, thereby forming graphene while continuously supplying the catalyst metal and greatly improving graphene quality.

The quality improvement can be maximized and growth time of graphene can thus be greatly shortened by providing separate chambers having different conditions.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. An apparatus for manufacturing graphene comprising:
a first chamber for supplying a carbon source under a first condition;
a second chamber for supplying a carbon source under a second condition;
a connector for connecting the first chamber to the second chamber; and
a feeder for continuously supplying a catalyst metal to the first chamber and the second chamber.

2. The apparatus according to claim 1, wherein the first condition is configured to increase a size of seeds of graphene.

3. The apparatus according to claim 2, wherein the first condition includes a lower partial pressure of carbon source than that of the second condition.

4. The apparatus according to claim 2, wherein the second condition is configured to fill gaps between the seeds and to form graphene.

5. The apparatus according to claim 1, wherein the feeder comprises:
a feed roll disposed at one side of the first chamber, the feed roll supplying the catalyst metal; and
a wind roll disposed at the other side of the second chamber, the wind roll winding the catalyst metal and supplying the catalyst metal in the form of a roll.

6. The apparatus according to claim 1, further comprising a third chamber for pre-treatment disposed at one side of the first chamber.

7. A method for manufacturing graphene comprising:
continuously supplying a catalyst metal to a first chamber and a second chamber;
supplying a carbon source to the first chamber to form graphene on the catalyst metal under a first condition; and
supplying a carbon source to the second chamber to form graphene on the catalyst metal under a second condition.

8. The method according to claim 7, wherein the first condition is configured to increase a size of seeds of graphene.

9. The method according to claim 7, wherein the first condition includes a lower partial pressure of carbon source than that of the second condition.

10. The method according to claim 7, wherein the first condition includes a temperature equal to or higher than that of the second condition.

11. The method according to claim 7, wherein the second condition is configured to fill gaps between the seeds and to form graphene.

12. The method according to claim 7, further comprising thermally treating the catalyst metal.

13. A method for manufacturing graphene comprising:
continuously supplying a catalyst metal to a first area and a second area having different conditions;
forming graphene on the catalyst metal in the first area under a first condition; and
carrying the catalyst metal in the second area and supplying a carbon source to the second area to form graphene under a second condition in a region in which graphene is formed under the first condition.

14. The method according to claim 13, wherein the first condition
configured to increase a size of seeds of graphene.

15. The method according to claim 13, wherein the first condition includes a lower partial pressure of carbon source than that of the second condition.

16. The method according to claim 13, wherein the first condition includes a temperature equal to or higher than that of the second condition.

17. The method according to claim 13, wherein the second condition is configured to fill gaps between the seeds and to form graphene.

18. The method according to claim 13, further comprising thermally treating the catalyst metal.

19. The method according to claim 13, wherein the first area and the second area are inner parts of a first chamber and a second chamber which are different from each other.

20-21. (canceled)
